(19) United States
(12) Patent Application Publication
(10) Pub. No.: US 2002/0142104 A1
(43) Pub. Date: Oct. 3, 2002

(54) Plasma treatment of organosilicate layers

(75) Inventors: Srinivas Nemani, San Jose, CA (US); Li-Qun Xia, Santa Clara, CA (US); Ellie Yieh, San Jose, CA (US)

Correspondence Address: Patent Counsel, Applied Materials, Inc., 3050 Bowers Avenue, P.O. Box 450A, Santa Clara, CA, 95052, US

(73) Assignee: Applied Materials, Inc.

(21) Appl. No.: 09/820,463

(22) Filed: Mar. 28, 2001

(51) Int. Cl. C08J 7/18; G03F 7/36

(52) U.S. Cl. 427/489; 430/312; 430/314; 430/316; 430/317; 216/79

(57) ABSTRACT

A method of forming an organosilicate layer for use in integrated circuit fabrication processes is provided. The organosilicate layer may be formed by reacting a gas mixture comprising a silicon source, a carbon source, and an oxygen source in the presence of an electric field. After the organosilicate layer is formed, it is treated with a plasma comprising one or more inert gases. The organosilicate layer is compatible with integrated circuit fabrication processes. In one integrated circuit fabrication process, the organosilicate layer is used as a bulk insulating material in a dual damascene structure.

### BACKGROUND OF THE DISCLOSURE

1. Field of the Invention

The invention relates to low dielectric constant (k) materials and, more particularly, to low dielectric constant (k) organosilicate layers, as well as the deposition thereof.

2. Description of the Background Art

Integrated circuits have evolved into complex devices that can include millions of components (e.g., transistors, capacitors, and resistors) on a single chip. The evolution of chip designs continually requires faster circuitry and greater circuit densities. The demands for greater circuit densities necessitate a reduction in the dimensions of the integrated circuit components.

As the dimensions of the integrated circuit components are reduced (e.g., sub-micron dimensions), the materials used to fabricate such components contribute to the electrical performance of such components. For example, low resistivity metal interconnects (e.g., aluminum (Al) and copper (Cu)) provide conductive paths between the components on integrated circuits.

Typically, the metal interconnects are electrically isolated from each other by a bulk insulating material. When the distance between adjacent metal interconnects and/or the thickness of the bulk insulating material has submicron dimensions, capacitive coupling potentially occurs between such interconnects. Capacitive coupling between adjacent metal interconnects may cause cross-talk and/or resistance-capacitance (RC) delay, which degrades the overall performance of the integrated circuit.

In order to minimize capacitive coupling between adjacent metal interconnects, low dielectric constant bulk insulating materials (e.g., dielectric constants less than about 3.0) are needed. Examples of low dielectric constant bulk insulating materials include silicates such as silicon dioxide (SiO₂), undoped silicate glass (USG), fluorosilicate glass (FSG), and organosilicate materials, among others.

In addition, a low dielectric constant (low k) barrier layer often separates the metal interconnects from the bulk insulating materials. The low dielectric constant barrier layer minimizes the diffusion of the metal from the interconnects into the bulk insulating material. Diffusion of the metal from the interconnects into the bulk insulating material is undesirable because such diffusion can affect the electrical performance of the integrated circuit (e.g., cross-talk and or RC delay), or render it inoperative.

Some integrated circuit components include multilevel interconnect structures (e.g., dual damascene structures). Multilevel interconnect structures can have two or more bulk insulating layers, low dielectric constant barrier layers, and metal layers stacked one on top of another. When low dielectric constant bulk insulating materials, such as, for example, organosilicate materials, are incorporated into a multilevel interconnect structure, overlying material layers can undesirably peel away from such bulk insulating material layers.

Thus, there is an ongoing need for a method of forming organosilicate material layers suitable for integrated circuit fabrication.

### SUMMARY OF THE INVENTION

A method of forming an organosilicate layer for use in integrated circuit fabrication processes is provided. The organosilicate layer may be formed by reacting a gas mixture comprising a silicon source, a carbon source, and an oxygen source in the presence of an electric field. After the organosilicate layer is formed, it is treated with a plasma comprising one or more inert gases.

The organosilicate layer is compatible with integrated circuit fabrication processes. In one integrated circuit fabrication process, the organosilicate layer is used as a bulk insulating material in a dual damascene structure. For such a structure, a preferred process sequence includes depositing a barrier layer on a metal layer formed on a substrate. After the barrier layer is deposited on the substrate, a first organosilicate layer is formed thereon. A hard mask layer is formed on the first organosilicate layer. The hard mask layer is patterned to define vias therein. Thereafter, a second organosilicate layer is formed on the patterned hard mask layer. The second organosilicate layer is patterned to define interconnects therethrough. The interconnects formed in the second organosilicate layer are positioned over the vias defined in the hard mask layer. After the second organosilicate layer is patterned, the vias defined in the hard mask layer are transferred into the first organosilicate layer. Thereafter, the dual damascene structure is completed by filling the vias and interconnects with a conductive material.

### BRIEF DESCRIPTION OF THE DRAWINGS

The teachings of the present invention can be readily understood by considering the following detailed description in conjunction with the accompanying drawings, in which:

FIG. 1 depicts a schematic illustration of an apparatus that can be used for the practice of embodiments described herein;

FIG. 2 depicts a schematic illustration of an alternate apparatus including a remote plasma source that can be used for the practice of embodiments described herein; and

FIGS. 3a-3i depict schematic cross-sectional views of a damascene structure at different stages of an integrated circuit fabrication sequence incorporating plasma treated organosilicate layers therein as low dielectric constant bulk insulating layers.

### DETAILED DESCRIPTION

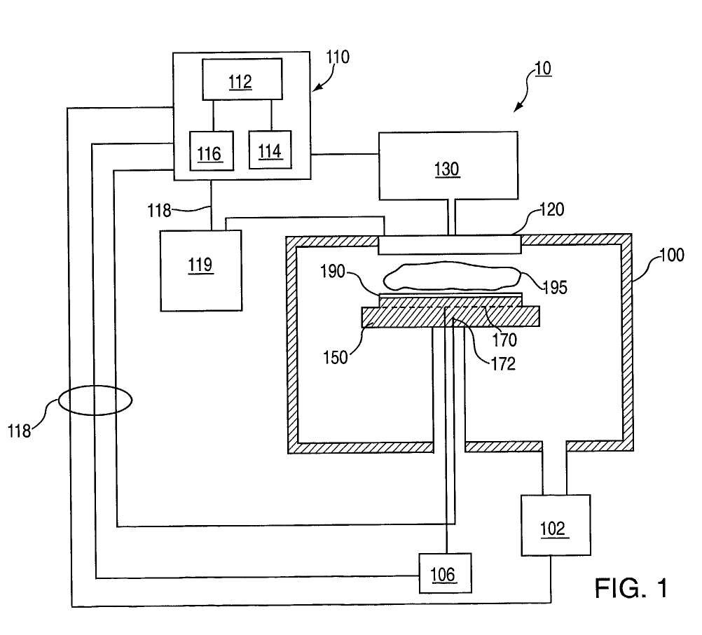

FIG. 1 is a schematic representation of a wafer processing system 10 that can be used to form organosilicate layers in accordance with embodiments described herein. System 10 typically comprises a process chamber 100, a gas panel 130, a control unit 110, along with other hardware components such as power supplies 119, 106 and vacuum pumps 102. Examples of wafer processing system 10 include plasma enhanced chemical vapor deposition (PECVD) chambers such as DXZ™ chambers, commercially available from Applied Materials, Inc., located in Santa Clara, Calif.

Details of wafer processing system 10 are described in commonly assigned U.S. patent application Serial No. 09/211,998, entitled “High Temperature Chemical Vapor Deposition Chamber”, filed on Dec. 14, 1998, and is herein incorporated by reference. The salient features of this system 10 are briefly described below.

The process chamber 100 generally houses a support pedestal 150, which is used to support a substrate such as a semiconductor wafer 190. The pedestal 150 can typically be moved in a vertical direction inside the chamber 100 using a displacement mechanism (not shown).

Depending on the specific process, the wafer 190 can be heated to some desired temperature prior to organosilicate layer deposition. For example, referring to FIG. 1, the wafer support pedestal 150 is heated by an embedded heater element 170. The pedestal 150 may be resistively heated by applying an electric current from an AC power supply 106 to the heater element 170. The wafer 190 is, in turn, heated by the pedestal 190.

A temperature sensor 172, such as a thermocouple, may also be embedded in the wafer support pedestal 150 to monitor the temperature of the pedestal in a conventional manner. The measured temperature can be used in a feedback loop to control the power supplied to the heater element 170, such that the wafer temperature can be maintained or controlled at a desired temperature which is suitable for the particular process application. The pedestal may optionally be heated using radiant heat (not shown).

A vacuum pump 102 is used to evacuate the process chamber 100 and to maintain the proper gas flows and pressure inside the chamber 100. A showerhead 120, through which process gases are introduced into the chamber 100, is located above the wafer support pedestal 150. The showerhead 120 is coupled to a gas panel 130, which controls and supplies various gases used in different steps of the process sequence.

The showerhead 120 and wafer support pedestal 150 also form a pair of spaced-apart electrodes. When an electric field is generated between these electrodes, the process gases introduced into the chamber 100 are ignited into a plasma. The electric field is generated by connecting the showerhead 120 to a source of radio frequency (RF) power (not shown) through a matching network (not shown). Alternatively, the RF power source and the matching network may be coupled to the wafer support 150, or coupled to both the showerhead 120 and the wafer support pedestal 150.

The electric field may optionally be generated by coupling the showerhead 120 to a source of mixed radio frequency (RF) power 119. Details of the mixed RF power source 119 are described in commonly assigned U.S. Pat. No. 6,041,734, entitled, “Use of an Asymmetric Waveform to Control Ion Bombardment During Substrate Processing”, issued Mar. 28, 2000, and is herein incorporated by reference.

Typically, the source of mixed RF power 119 under the control of a controller unit 110 provides a high frequency power (e.g., RF power in a range of about 10 MHz to about 15 MHz) as well as a low frequency power (e.g., RF power in a range of about 150 KHz to about 450 KHz) to the showerhead 120. Both the high frequency RF power and the low frequency RF power may be coupled to the showerhead 120 through a matching network (not shown). The high frequency RF power and the low frequency RF power may optionally be coupled to the wafer support pedestal 150, or alternatively one may be coupled to the showerhead 120 and the other may be coupled to the wafer support pedestal 150.

Plasma enhanced chemical vapor deposition (PECVD) techniques promote excitation and/or disassociation of the reactant gases by the application of the electric field to a reaction zone 195 near the substrate surface, creating a plasma of reactive species. The reactivity of the species in the plasma reduces the energy required for a chemical reaction to take place, in effect lowering the required temperature for such PECVD processes.

Proper control and regulation of the gas flows through the gas panel 130 is performed by mass flow controllers (not shown) and the controller unit 110. The showerhead 120 allows process gases from the gas panel 130 to be uniformly introduced and distributed in the process chamber 100.

Illustratively, the control unit 110 comprises a central processing unit (CPU) 113, as well as support circuitry 114, and memories containing associated control software 116. The control unit 110 is responsible for automated control of the numerous steps required for wafer processing—such as wafer transport, gas flow control, mixed RF power control, temperature control, chamber evacuation, and other steps. Bi-directional communications between the control unit 110 and the various components of the wafer processing system 10 are handled through numerous signal cables collectively referred to as signal buses 118, some of which are illustrated in FIG. 1.

The central processing unit (CPU) 113 may be one of any form of general purpose computer processor that can be used in an industrial setting for controlling process chambers as well as sub-processors. The computer may use any suitable memory, floppy disk drive, hard drive, or any other form of digital storage, local or remote. Various support circuits may be coupled to the CPU for supporting the processor in a conventional manner. Process sequence routines as required may be stored in the memory or executed by a second CPU that is remotely located.

The process sequence routines are executed after the substrate 190 is positioned on the wafer support pedestal 150. The process sequence routines, when executed, transform the general purpose computer into a specific process computer that controls the chamber operation so that the deposition process is performed. Alternatively, the chamber operation may be controlled using remotely located hardware, as an application specific integrated circuit or other type of hardware implementation, or a combination of software and hardware.

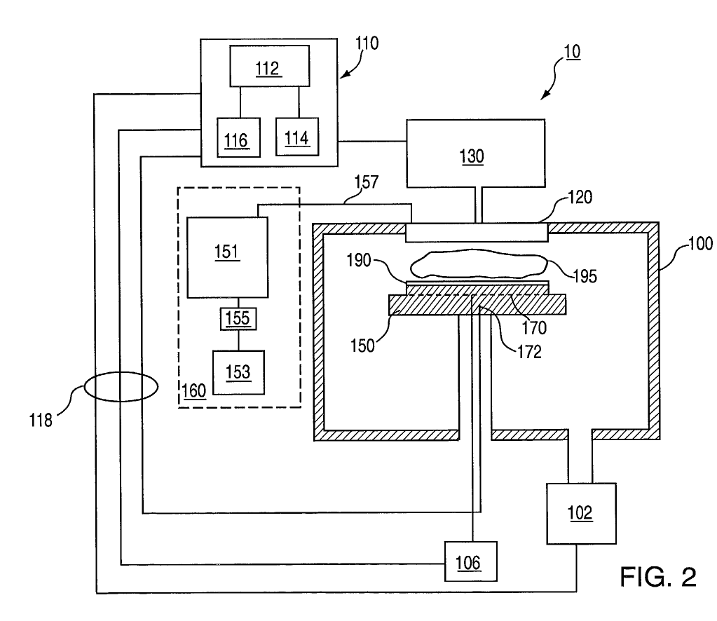

Optionally, a remote plasma source 160 may be coupled to wafer processing system 10, as shown in FIG. 2, to provide a remotely generated plasma to the process chamber 100. The remote plasma source 160 includes a gas supply 153, a gas flow controller 155, a plasma chamber 151, and a chamber inlet 157. The gas flow controller 155 controls the flow of process gas from the gas supply 153 to the plasma chamber 151.

A remote plasma may be generated by applying an electric field to the process gas in the plasma chamber 151, creating a plasma of reactive species. Typically, the electric field is generated in the plasma chamber 151 using a RF power source (not shown). The reactive species generated in the remote plasma source 160 are introduced into the process chamber 100 through inlet 157.

Organosilicate Layer Formation

An organosilicate layer is formed by reacting a gas mixture comprising a silicon source, a carbon source, and an oxygen source. The silicon source may be an organosilane compound. Suitable organosilane compounds may have the general formula SiₓC_{y}H_{z}, where x has a range from 1 to 2, y has a range from 1 to 6, and z has a range from 4 to 18. For example, methylsilane (SiCH₆), dimethylsilane (SiC₂H₈), trimethylsilane (SiC₃H₁₀), tetramethylsilane (SiC₄H₁₂), bis(methylsilano)methane (Si₂C₃H₁₂), 1,2-bis(methylsilano)ethane Si₂C₄H₁₄), and diethylsilane (SiC₄H₁₂), among others may be used as the organosilane compound. Silane (SiH₄), disilane (Si₂H₆), methane (CH₄), and combinations thereof, may also be used as the silicon source and the carbon source.

Alternatively, the organosilane compound may have the general formula SiₐC_{b}H_{c}O_{d}, where a has a range from 1 to 2, b has a range from 1 to 10, c has a range from 6 to 30, and d has a range from 1 to 6. For example, methoxysilane (SiCH₆O), dimethyldimethoxysilane (SiC₄H₁₂O₂), diethyldiethoxysilane (SiC₈H₂₀O₂), dimethyldiethoxysilane (SiC₆H₁₆O₂), diethyldimethoxysilane (SiC₆H₁₆O₂), and hexamethyldisiloxane (Si₂C₆H₁₈O), among others are also suitable organosilane compounds.

Oxygen (O₂), ozone (O₃), nitrous oxide (N₂O), carbon monoxide (CO), carbon dioxide (CO₂), or combinations thereof, among others, may be used for the carbon source.

The gas mixture may optionally include an inert gas. Helium (He), argon (Ar), neon (Ne), and xenon (Xe), as well as combinations thereof, among others, may be used for the inert gas.

In general, the following deposition process parameters can be used to form the organosilicate layer in a CVD process chamber similar to that shown in FIG. 1 or FIG. 2. The process parameters range from a wafer temperature of about 50° C. to about 500° C., a chamber pressure of about 1 torr to about 500 torr, a silicon source and/or carbon source flow rate of about 10 sccm to about 2,000 sccm, an oxygen source flow rate of about 10 sccm to about 200 sccm, an inert gas flow rate of about 10 sccm to about 1,000 sccm, a plate spacing of about 300 mils to about 600 mils, and an RF power of about 1 watt/cm² to about 500 watts/cm² (for either of the single or mixed frequency RF powers). The above process parameters provide a deposition rate for the organosilicate layer in the range of about 0.1 microns/minute to about 2 microns/minute when implemented on a 200 mm (millimeter) substrate in a deposition chamber available from Applied Materials, Inc., Santa Clara, Calif.

Other deposition chambers are within the scope of the invention, and the parameters listed above may vary according to the particular deposition chamber used to form the organosilicate layer. For example, other deposition chambers may have a larger (e.g., configured to accommodate 300 mm substrates) or smaller volume, requiring gas flow rates that are larger or smaller than those recited for deposition chambers available from Applied Materials, Inc., Santa Clara, Calif.

After the organosilicate layer is formed, it is treated with a plasma comprising oxygen (O₂) and hydrogen (H₂). An inert gas, such as, for example, helium (He), argon (Ar), nitrogen (N₂), and combinations thereof, among others, may be added to the plasma.

In general, the following process parameters may be used to plasma treat the organosilicate layer in a process chamber similar to that shown in FIG. 1 or FIG. 2. The process parameters range from a wafer temperature of about 50° C. to about 400° C., a chamber pressure of about 1 torr to about 10 torr, an oxygen (O₂)/hydrogen (H₂) gas flow rate of about 20 sccm to about 500 sccm, an inert gas flow rate of about 500 sccm to about 5,000 sccm, and a radio frequency (RF) power of about 1 watt/cm² to about 100 watts/cm². The organosilicate layer is plasma treated for less than about 10 minutes.

The plasma treatment improves the adhesion of overlying material layers to the organosilicate layer. It is believed that the fracture strength of plasma treated organosilicate layers is greater than that of untreated layers, minimizing cracking of the treated organosilicate layer so as to improve the adhesion of material layers thereto.

Additionally, the plasma treatment is believed to densify the organosilicate layers, as well as make them less hydrophobic with improved surface wetting properties. Also, the plasma treatment is believed to improve the etch selectivity of the organosilicate layer with respect to untreated layers.

Alternatively, an underlying material layer (e.g., silicon carbide) may be plasma treated using the process parameters described above prior to organosilicate layer deposition. Such a pre-deposition plasma treatment step is believed to clean the surface of the underlying material layer.

Integrated Circuit Fabrication Process

Damascene Structure Incorporating a Plasma Treated Organosilicate Layer

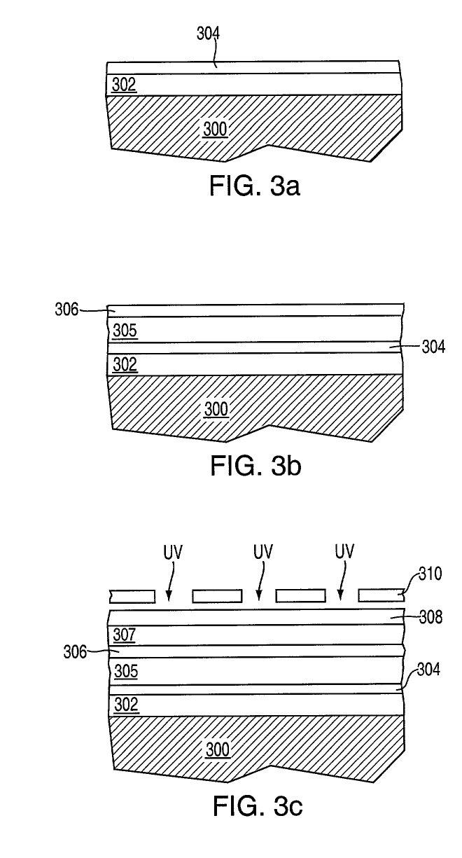

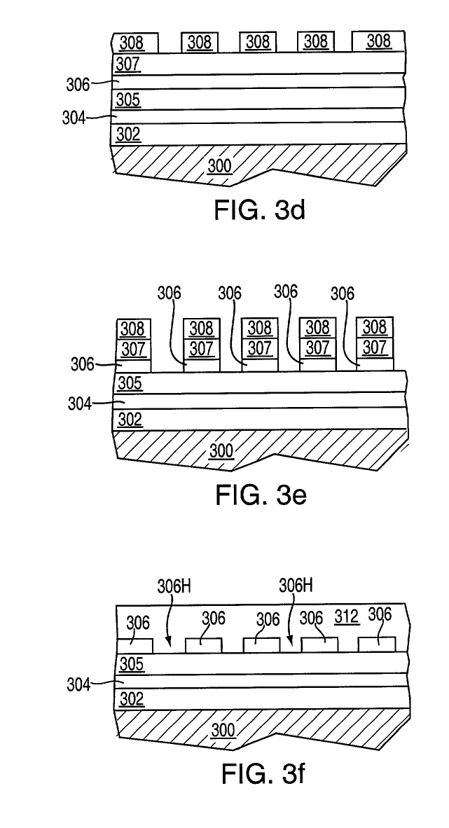

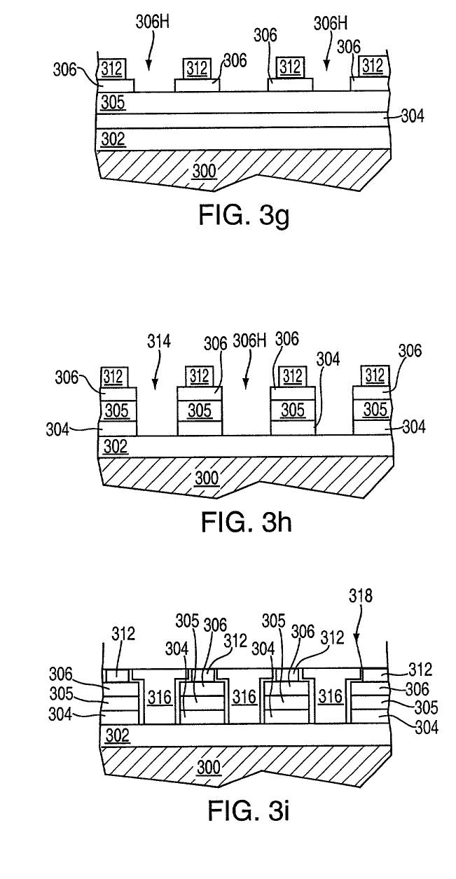

FIGS. 3a-3i illustrate schematic cross-sectional views of a substrate 300 at different stages of a dual damascene structure fabrication sequence incorporating organosilicate layers therein. Dual damascene structures are typically used to form multi-layer metal interconnects on integrated circuits. Depending on the specific stage of processing, substrate 300 may correspond to a silicon wafer, or other material layer that has been formed on the substrate 300. FIG. 3a, for example, illustrates a cross-sectional view of a substrate 300 having a metal layer 302 (e.g., copper (Cu), aluminum (Al), tungsten (W)) formed thereon.

FIG. 3a illustrates one embodiment in which the substrate 300 is silicon having a copper (Cu) layer formed thereon. The copper layer 302 has a thickness of about 5,000 Å to about 5 microns depending on the size of the structure to be fabricated.

A barrier layer 304 is formed on the copper layer 302. The barrier layer 304 may be a silicon carbide layer. The barrier layer 304 has a thickness of about 200 Å to about 1,000 Å.

Referring to FIG. 3b, a first organosilicate layer 305 is formed on the barrier layer 304. The first organosilicate layer 305 is formed on the barrier layer 304 and plasma treated according to the process parameters described above. The thickness of the first organosilicate layer 305 is variable depending on the specific stage of processing. Typically, the first organosilicate layer 305 has a thickness of about 5,000 Å to about 10,000 Å.

A hardmask layer 306 is formed on the first organosilicate layer 305. The hardmask layer 306 may be a silicon carbide layer. The thickness of the hardmask layer 306 is variable depending on the specific stage of processing. Typically, the hardmask layer 306 has a thickness of about 200 Å to about 1,000 Å.

Referring to FIG. 3c, a layer of energy sensitive resist material 308 is formed on the hardmask layer 306. The layer of energy sensitive resist material 308 may be spin coated on the substrate to a thickness within a range of about 4,000 Å to about 10,000 Å. Most energy sensitive resist materials are sensitive to ultraviolet (UV) radiation having a wavelength less than about 450 nm (nanometers). Deep ultraviolet (DUV) resist materials are sensitive to UV radiation having wavelengths less than about 250 nm.

Dependant on the etch chemistry of the energy sensitive resist material used in the fabrication sequence, an intermediate layer 307 may be formed on the hardmask layer 306. When the energy sensitive resist material 308 and the hardmask layer 306 can be etched using the same chemical etchants or when resist poisoning may occur, the intermediate layer 307 functions as a mask for the hardmask layer 306. The intermediate layer 307 is conventionally formed on the hardmask layer 306. The intermediate layer 307 may be a silicon carbide cap layer, an oxide, amorphous silicon, or other suitable material layer.

An image of a pattern is introduced into the layer of energy sensitive resist material 308 by exposing such energy sensitive resist material 308 to UV radiation via mask 310. The image of the pattern introduced into the layer of energy sensitive resist material 308 is developed in an appropriate developer to define the pattern therethrough, as shown in FIG. 3d.

Thereafter, referring to FIG. 3e, the pattern defined in the energy sensitive resist material 308 is transferred through the hardmask layer 306. The pattern is transferred through the hardmask layer 306 using the energy sensitive resist material 308 as a mask. The pattern is transferred through the hardmask layer 306 using an appropriate chemical etchant. For example, fluorocarbon compounds such as trifluoromethane (CHF₃) may be used to chemically etch a silicon carbide hardmask layer.

Alternatively, when the intermediate layer 307 is present, the pattern defined in the energy sensitive resist material 308 is first transferred through the intermediate layer 306 using the energy sensitive resist material 308 as a mask. Thereafter, the pattern is transferred through the hardmask layer 306 using the intermediate layer 307 as a mask. The pattern is transferred through both the intermediate layer 307 and the hardmask layer 306 using appropriate chemical etchants.

After the hardmask layer 306 is patterned, a second organosilicate layer 312 is deposited thereover, as illustrated in FIG. 3f. The second organosilicate layer 312 is deposited and plasma treated according to the process parameters described above. The thickness of the second organosilicate layer 312 is variable depending on the specific stage of processing. Typically, the second organosilicate layer 312 has a thickness of about 5,000 Å to about 10,000 Å.

The second organosilicate layer 312 is then patterned to define interconnect lines 314, as illustrated in FIG. 3g, preferably using conventional lithography processes described above. The interconnect lines 314 formed in the second organosilicate layer 312 are positioned over the via openings 306H formed in the hardmask layer 306. Thereafter, as shown in FIG. 3h, the vias 306H are transferred through the first organosilicate layer 304 and the barrier layer 304 by etching them using reactive ion etching or other anisotropic etching techniques.

Referring to FIG. 3i, the interconnect lines 314 and the vias 306H are filled with a conductive material 316 such as aluminum (Al), copper (Cu), tungsten (W), or combinations thereof. Preferably copper (Cu) is used to fill the interconnect lines 314 and the vias 306H due to its low resistivity (resistivity of about 1.7 μΩ-cm). The conductive material 316 may be deposited using chemical vapor deposition (CVD) techniques, physical vapor deposition (PVD) techniques, electroplating techniques, or combinations thereof, to form the damascene structure.

Additionally, a barrier layer 318 such as tantalum (Ta), tantalum nitride (TaN), or other suitable barrier material may be deposited conformably on the sidewalls of the interconnect lines 314 and the vias 306H, before filling them with the conductive material 316, to prevent metal migration into the surrounding first and second organosilicate layers 304, 312, as well as the barrier layer 304 and the hardmask layer 306.

Alternatively, the damascene structure described above may be formed by depositing the complete multi-layer structure, and thereafter defining the vias and interconnect lines therein.

Although several preferred embodiments which incorporate the teachings of the present invention have been shown and described in detail, those skilled in the art can readily devise many other varied embodiments that still incorporate these teachings.

What is claimed is:

1. A method of thin film deposition for integrated circuit fabrication, comprising:
(a) providing a substrate;
(b) forming an organosilicate layer on the substrate; and
(c) treating the organosilicate layer with a plasma.

2. The method of claim 1 further, comprising:
(d) treating the substrate with a plasma prior to forming the organosilicate layer thereon.

3. The method of claim 2 wherein the plasmas of steps (b) and (d) are generated in a reaction chamber by applying an electric field to a gas mixture comprising oxygen (O₂) and hydrogen (H₂).

4. The method of claim 3 wherein the gas mixture further comprises one or more inert gases are selected from the group of helium (He), argon (Ar), nitrogen (N₂), and combinations thereof.

5. The method of claim 3 wherein the electric field is a radio frequency (RF) power.

6. The method of claim 5 wherein the RF power is within a range of about 1 watt/cm² to about 100 watts/cm².

7. The method of claim 3 wherein the reaction chamber is maintained at a pressure within a range of about 1 torr to about 10 torr.

8. The method of claim 3 wherein the plasma treatment is performed at a temperature within a range of about 50 ° C. to about 400 ° C.

9. The method of claim 3 wherein the oxygen (O₂)/hydrogen (H₂) gases are provided to the reaction chamber at flow rates within a range of about 500 sccm to about 5,000 sccm.

10. The method of claim 4 wherein the one or more inert gases are provided to the reaction chamber at flow rates within a range of about 500 sccm to about 5,000 sccm.

11. The method of claim 1 wherein the organosilicate layer is formed by:
(e) positioning the substrate in a deposition chamber;
(f providing a gas mixture to the deposition chamber, wherein the gas mixture comprises a silicon source, a carbon source, and an oxygen source; and
(g) applying an electric field to the gas mixture in the deposition chamber to form the carbon-containing silicate layer on the substrate.

12. The method of claim 11 wherein the silicon source and the carbon source comprise an organosilane compound having the general formula SiₐC_{b}H_{c}O_{d}, where a has a range between 1 and 2, b has a range between 1 and 10, c has a range between 6 and 30, and d has a range between 0 and 6.

13. The method of claim 12 wherein the organosilane compound is selected from the group of methylsilane (SiCH₆), dimethylsilane (SiC₂H₈), trimethylsilane (SiC₃H₁₀), tetramethylsilane (SiC₄H₁₂), methoxysilane (SiCH₆O), dimethyldimethoxysilane (SiC₄H₁₂O₂), diethyldiethoxysilane (SiC₈H₁₈O₂), dimethyldiethoxysilane (SiC₆H₁₆O₂), diethyldimethoxysilane (SiC₆H₁₆O₂), hexamethyldisiloxane (Si₂C₆H₁₈O), bis(methylsilano)methane (Si₂C₃H₁₂), 1,2-bis(methylsilano)ethane (Si₂C₄H₁₄), and combinations thereof.

14. The method of claim 11 wherein the oxygen source is selected from the group of nitrous oxide (N₂O), oxygen (O₂), ozone (03), carbon monoxide (CO), carbon dioxide (CO₂), and combinations thereof.

15. The method of claim 11 wherein the electric field applied to the gas mixture in the deposition chamber is a radio frequency (RF) power.

16. The method of claim 15 wherein the RF power is within a range of about 1 watt/cm² to about 500 watts/cm².

17. The method of claim 11 wherein the deposition chamber is maintained at a pressure between about 1 torr to about 500 torr.

18. The method of claim 12 wherein the organosilane compound is provided to the deposition chamber at a flow rate in a range of about 50 sccm to about 1,000 sccm.

19. The method of claim 11 wherein the oxygen source is provided to the deposition chamber at a flow rate in a range of about 10 sccm to about 200 sccm.

20. The method of claim 12 wherein the ratio of the oxygen source to the organosilane compound is about 1:1 to about 1:5.

21. The method of claim 11 wherein the deposition chamber is maintained at a temperature between about 50° C. to about 500° C.

22. The method of claim 11 wherein the gas mixture further comprises an inert gas.

23. The method of claim 22 wherein the inert gas is selected from the group of helium (He), argon (Ar), neon (Ne), xenon (Xe), and combinations thereof.

24. The method of claim 22 wherein the inert gas is provided to the deposition chamber at a flow rate in a range of about 10 sccm to about 1,000 sccm.

25. A computer storage medium containing a software routine that, when executed, causes a general purpose computer to control a deposition chamber using a layer deposition method, comprising:
(a) providing a substrate;
(b) forming an organosilicate layer on a substrate; and
(c) treating the organosilicate layer with a plasma.

26. The computer storage medium of claim 25 further, comprising:
(d) treating the substrate with a plasma prior to forming the organosilicate layer thereon.

27. The computer storage medium of claim 26 wherein the plasmas of step (b) and (d) are generated in a reaction chamber by applying an electric field to a gas mixture comprising oxygen (O₂) and hydrogen (H₂).

28. The computer storage medium of claim 27 wherein the gas mixture further comprises one or more inert gases are selected from the group of helium (He), argon (Ar), nitrogen (N₂), and combinations thereof.

29. The computer storage medium of claim 27 wherein the electric field is a radio frequency (RF) power.

30. The computer storage medium of claim 29 wherein the RF power is within a range of about 1 watt/cm² to about 100 watts/cm².

31. The computer storage medium of claim 27 wherein the reaction chamber is maintained at a pressure within a range of about 1 torr to about 10 torr.

32. The computer storage medium of claim 27 wherein the plasma treatment step is performed at a temperature within a range of about 50° C. to about 400° C.

33. The computer storage medium of claim 27 wherein the oxygen (O₂)/hydrogen (H₂) gases are provided to the reaction chamber at flow rates within a range of about 500 sccm to about 5,000 sccm.

34. The computer storage medium of claim 28 wherein the one or more inert gases are provided to the reaction chamber at a flow rate within a range of about 500 sccm to about 5,000 sccm.

35. The computer storage medium of claim 26 wherein the organosilicate layer is formed by:
(e) positioning the substrate in a deposition chamber;
(e) providing a gas mixture to the deposition chamber, wherein the gas mixture comprises a silicon source, a carbon source, and an oxygen source; and
(g) applying an electric field to the gas mixture in the deposition chamber to form the organosilicate layer on the substrate.

36. The computer storage medium of claim 35 wherein the silicon source and the carbon source comprise an organosilane compound having the general formula SiₐC_{b}H_{c}O_{d}, where a has a range between 1 and 2, b has a range between 1 and 10, c has a range between 6 and 30, and d has a range between 0 and 6.

37. The computer storage medium of claim 36 wherein the organosilane compound is selected from the group of methylsilane (SiCH₆), dimethylsilane (SiC₂H₈), trimethylsilane (SiC₃H₁₀), tetramethylsilane (SiC₄H₁₂), methoxysilane (SiCH₆O), dimethyldimethoxysilane (SiC₄H₁₂O₂), diethyldiethoxysilane (SiC₈H₁₈O₂), dimethyldiethoxysilane (SiC₆H₁₆O₂), diethyldimethoxysilane (SiC₆H₁₆O₂), hexamethyldisiloxane (Si₂C₆H₁₈O), bis(methylsilano)methane (Si₂C₃H₁₂), 1,2-bis(methylsilano)ethane (Si₂C₄H₁₄), and combinations thereof.

38. The computer storage medium of claim 35 wherein the oxygen source is selected from the group of nitrous oxide (N₂O), oxygen (O₂), ozone (O₃), carbon monoxide (CO), carbon dioxide (CO₂), and combinations thereof.

39. The computer storage medium of claim 35 wherein the electric field applied to the gas mixture in the deposition chamber is a radio frequency (RF) power.

40. The computer storage medium of claim 39 wherein the RF power is within a range of about 1 watt/cm² to about 500 watts/cm².

41. The computer storage medium of claim 35 wherein the deposition chamber is maintained at a pressure between about 1 torr to about 500 torr.

42. The computer storage medium of claim 36 wherein the organosilane compound is provided to the deposition chamber at a flow rate in a range of about 50 sccm to about 1,000 sccm.

43. The computer storage medium of claim 35 wherein the oxygen source is provided to the deposition chamber at a flow rate in a range of about 10 sccm to about 200 sccm.

44. The computer storage medium of claim 36 wherein the ratio of the oxygen source to the organosilane compound is about 1:1 to about 1:5.

45. The computer storage medium of claim 35 wherein the deposition chamber is maintained at a temperature between about 50° C. to about 500° C.

46. The computer storage medium of claim 35 wherein the gas mixture further comprises an inert gas.

47. The computer storage medium of claim 46 wherein the inert gas is selected from the group of helium (He), argon (Ar), neon (Ne), xenon (Xe), and combinations thereof.

48. The computer storage medium of claim 46 wherein the inert gas is provided to the deposition chamber at a flow rate in a range of about 10 sccm to about 1,000 sccm.

49. A method of fabricating a damascene structure, comprising:
(a) forming a barrier layer on a substrate having a metal layer thereon;
(b) forming a first organosilicate layer on the barrier layer;
(c) treating the first organosilicate layer with a plasma;
(d) forming a hardmask layer on the first organosilicate layer;
(e) patterning the hardmask layer to define vias therein;
(f) forming a second organosilicate layer on the patterned hardmask layer;
(g) treating the second organosilicate layer with a plasma;
(h) patterning the second organosilicate layer to define interconnects therein, wherein the interconnects are positioned over the vias defined in the hardmask layer;
(i) etching the first organosilicate layer to form vias therethrough; and
(j) filling the vias and interconnects with a conductive material.

50. The method of claim 49 further, comprising:
(k) treating the substrate with a plasma prior to forming the first and second organosilicate layers of steps (b) and (f).

51. The method of claim 49 wherein the conductive material filling the vias and interconnects is selected from the group of copper (Cu), aluminum (Al), tungsten (W), and combinations thereof.

52. The method of claim 49 wherein the plasmas of either step (c) and (g) are generated in a reaction chamber by applying an electric field to a gas mixture comprising oxygen (O₂) and hydrogen (H₂).

53. The method of claim 52 wherein the gas mixture further comprises one or more inert gases are selected from the group of helium (He), argon (Ar), nitrogen (N₂), and combinations thereof.

54. The method of claim 52 wherein the electric field is a radio frequency (RF) power.

55. The method of claim 54 wherein the RF power is within a range of about 1 watt/cm² to about 100 watts/cm².

56. The method of claim 52 wherein the reaction chamber is maintained at a pressure within a range of about 1 torr to about 10 torr.

57. The method of claim 52 wherein the plasma treatment is performed at a temperature within a range of about 50° C. to about 400° C.

58. The method of claim 52 wherein the oxygen (O₂)/hydrogen (H₂) gases are provided to the reaction chamber at flow rates within a range of about 500 sccm to about 5,000 sccm.

59. The method of claim 53 wherein the one or more inert gases are provided to the reaction chamber at a flow rate within a range of about 500 sccm to about 5,000 sccm.

60. The method of claim 49 wherein the first and second organosilicate layers of either steps (b) or (f) is formed by:
positioning the substrate in a deposition chamber;
providing a gas mixture to the deposition chamber, wherein the gas mixture comprises a silicon source, a carbon source, and an oxygen source; and
applying an electric field to the gas mixture in the deposition chamber to form the organosilicate layer on the substrate.

61. The method of claim 60 wherein the silicon source and the carbon source comprise an organosilane compound having the general formula SiₐC_{b}H_{c}O_{d}, where a has a range between 1 and 2, b has a range between 1 and 10, c has a range between 6 and 30, and d has a range between 0 and 6.

62. The method of claim 61 wherein the organosilane compound is selected from the group of methylsilane (SiCH₆), dimethylsilane (SiC₂H₈), trimethylsilane (SiC₃H₁₀), tetramethylsilane (SiC₄H₁₂), methoxysilane (SiCH₆O), dimethyldimethoxysilane (SiC₄H₁₂O₂), diethyldiethoxysilane (SiC₈H₁₈O₂), dimethyldiethoxysilane (SiC₆H₁₆O₂), diethyldimethoxysilane (SiC₆H₁₆O₂), hexamethyldisiloxane (Si₂C₆H₁₈O), bis(methylsilano)methane (Si₂C₃H₁₂), 1,2-bis(methylsilano)ethane (Si₂C₄H₁₄), and combinations thereof.

63. The method of claim 60 wherein the oxygen source is selected from the group of nitrous oxide (N₂O), oxygen (O₂), ozone (O₃), carbon monoxide (CO), carbon dioxide (CO₂), and combinations thereof.

64. The method of claim 60 wherein the electric field applied to the gas mixture in the deposition chamber is a radio frequency (RF) power.

65. The method of claim 64 wherein the RF power is within a range of about 1 watt/cm² to about 500 watts/cm².

66. The method of claim 60 wherein the deposition chamber is maintained at a pressure between about 1 torr to about 500 torr.

67. The method of claim 61 wherein the organosilane compound is provided to the deposition chamber at a flow rate in a range of about 50 sccm to about 1,000 sccm.

68. The method of claim 60 wherein the oxygen source is provided to the deposition chamber at a flow rate in a range of about 10 sccm to about 200 sccm.

69. The method of claim 61 wherein the ratio of the oxygen source to the organosilane compound is about 1:1 to about 1:5.

70. The method of claim 60 wherein the deposition chamber is maintained at a temperature between about 50° C. to about 500° C.

71. The method of claim 60 wherein the gas mixture further comprises an inert gas.

72. The method of claim 71 wherein the inert gas is selected from the group of helium (He), argon (Ar), neon (Ne), xenon (Xe), and combinations thereof.

73. The method of claim 71 wherein the inert gas is provided to the deposition chamber at a flow rate in a range of about 10 sccm to about 1,000 sccm.
